(19) United States
(12) Patent Application Publication
(10) Pub. No.: US 2024/0398027 A1
(43) Pub. Date: Dec. 5, 2024

(54) AEROSOL-GENERATING DEVICE AND OPERATION METHOD THEREOF

(71) Applicant: KT&G CORPORATION, Daejeon (KR)

(72) Inventors: Hyungjin JUNG, Seoul (KR); Taehun KIM, Yongin-si Gyeonggi-do (KR); Jueon PARK, Seoul (KR); Jungho HAN, Daejeon (KR)

(73) Assignee: KT&G CORPORATION, Daejeon (KR)

(21) Appl. No.: 18/695,291

(22) PCT Filed: Oct. 25, 2022
(86) PCT No.: PCT/KR2022/016385

§ 371 Date: Mar. 25, 2024

(30) Foreign Application Priority Data
Oct. 26, 2021 (KR) 10-2021-0144047
Mar. 21, 2022 (KR) 10-2022-0034945

(51) Int. Cl. A24F 40/51; A24F 40/10; A24F 40/20; A24F 40/30; A24F 40/57; G01R 27/08; G01R 31/3835

(52) U.S. Cl. CPC A24F 40/51; A24F 40/10; A24F 40/57; G01R 27/08; G01R 31/3835; A24F 40/20; A24F 40/30

(57) ABSTRACT

An aerosol-generating device and an operation method thereof are disclosed. The aerosol-generating device of the disclosure includes a heater configured to heat an aerosol-generating substance, a battery configured to supply power to the heater, a resistance detection sensor configured to output a signal corresponding to the resistance of the heater, a switching element electrically connected to the heater, and a controller configured to control operation of the switching element. The controller performs control such that the switching element is turned on in a first period in which power is supplied to the heater, determines a duty ratio based on the resistance of the heater corresponding to a signal from the resistance detection sensor in the first period, and adjusts switching operation of the switching element based on the determined duty ratio in a second period after the first period in which power is supplied to the heater.

### TECHNICAL FIELD

The present disclosure relates to an aerosol-generating device and an operation method thereof.

### BACKGROUND ART

An aerosol-generating device is a device that extracts certain components from a medium or a substance by forming an aerosol. The medium may contain a multicomponent substance. The substance contained in the medium may be a multicomponent flavoring substance. For example, the substance contained in the medium may include a nicotine component, an herbal component, and/or a coffee component. Recently, various research on aerosol-generating devices has been conducted.

### DISCLOSURE

### Technical Problem

It is an object of the present disclosure to solve the above and other problems.

It is another object of the present disclosure to provide an aerosol-generating device and an operation method thereof capable of accurately determining the resistance of a heater while the heater is heated.

It is still another object of the present disclosure to provide an aerosol-generating device and an operation method thereof capable of preventing the temperature of a heater from being lowered while the resistance of the heater is detected.

It is still another object of the present disclosure to provide an aerosol-generating device and an operation method thereof capable of minimizing overdischarge of a battery while a heater is heated.

### Technical Solution

An aerosol-generating device according to an aspect of the present disclosure for accomplishing the above and other objects may include a heater configured to heat an aerosol-generating substance, a battery configured to supply power to the heater, a resistance detection sensor configured to output a signal corresponding to the resistance of the heater, a switching element electrically connected to the heater, and a controller configured to control operation of the switching element. The controller may perform control such that the switching element is turned on in a first period in which power is supplied to the heater, may determine a duty ratio based on the resistance of the heater corresponding to a signal from the resistance detection sensor in the first period, and may adjust switching operation of the switching element based on the determined duty ratio in a second period after the first period in which power is supplied to the heater.

An operation method of an aerosol-generating device according to an aspect of the present disclosure for accomplishing the above and other objects may include turning on a switching element electrically connected to a heater in a first period in which power is supplied to the heater heating an aerosol-generating substance from a battery, determining, in the first period, a duty ratio based on a signal from a resistance detection sensor configured to output a signal corresponding to the resistance of the heater, and adjusting switching operation of the switching element based on the determined duty ratio in a second period after the first period in which power is supplied to the heater from the battery.

### Advantageous Effects

According to at least one of embodiments of the present disclosure, it may be possible to accurately determine the resistance of a heater while the heater is heated.

According to at least one of embodiments of the present disclosure, it may be possible to prevent the temperature of a heater from being lowered while the resistance of the heater is detected.

According to at least one of embodiments of the present disclosure, it may be possible to minimize overdischarge of a battery while a heater is heated.

Additional applications of the present disclosure will become apparent from the following detailed description. However, because various changes and modifications will be clearly understood by those skilled in the art within the spirit and scope of the present disclosure, it should be understood that the detailed description and specific embodiments, such as preferred embodiments of the present disclosure, are merely given by way of example.

### DESCRIPTION OF DRAWINGS

The above and other objects, features and other advantages of the present disclosure will be more clearly understood from the following detailed description taken in conjunction with the accompanying drawings, in which:

FIG. 1 is a block diagram of an aerosol-generating device according to an embodiment of the present disclosure;

FIGS. 2 to 4 are views for explaining an aerosol-generating device according to embodiments of the present disclosure;

FIGS. 5 and 6 are views for explaining a stick according to embodiments of the present disclosure;

FIG. 7 is a diagram for explaining the configuration of the aerosol-generating device according to an embodiment of the present disclosure;

FIG. 8 is a flowchart showing an operation method of the aerosol-generating device according to an embodiment of the present disclosure;

FIGS. 9 and 10 are diagrams for explaining the operation of an aerosol-generating device according to an embodiment of the present disclosure;

FIG. 11 is a flowchart showing an operation method of the aerosol-generating device according to an embodiment of the present disclosure; and

FIG. 12 is a diagrams for explaining the operation of an aerosol-generating device according to an embodiment of the present disclosure;

### BEST MODE

Hereinafter, the embodiments disclosed in the present specification will be described in detail with reference to the accompanying drawings. The same or similar elements are denoted by the same reference numerals even though they are depicted in different drawings, and redundant descriptions thereof will be omitted.

In the following description, with respect to constituent elements used in the following description, the suffixes “module” and “unit” are used only in consideration of facilitation of description. The “module” and “unit” are do not have mutually distinguished meanings or functions.

In addition, in the following description of the embodiments disclosed in the present specification, a detailed description of known functions and configurations incorporated herein will be omitted when the same may make the subject matter of the embodiments disclosed in the present specification rather unclear. In addition, the accompanying drawings are provided only for a better understanding of the embodiments disclosed in the present specification and are not intended to limit the technical ideas disclosed in the present specification. Therefore, it should be understood that the accompanying drawings include all modifications, equivalents, and substitutions within the scope and sprit of the present disclosure.

It will be understood that the terms “first”, “second”, etc., may be used herein to describe various components. However, these components should not be limited by these terms.

These terms are only used to distinguish one component from another component.

It will be understood that when a component is referred to as being “connected to” or “coupled to” another component, it may be directly connected to or coupled to another component. However, it will be understood that intervening components may be present. On the other hand, when a component is referred to as being “directly connected to” or “directly coupled to” another component, there are no intervening components present.

As used herein, the singular form is intended to include the plural forms as well, unless the context clearly indicates otherwise.

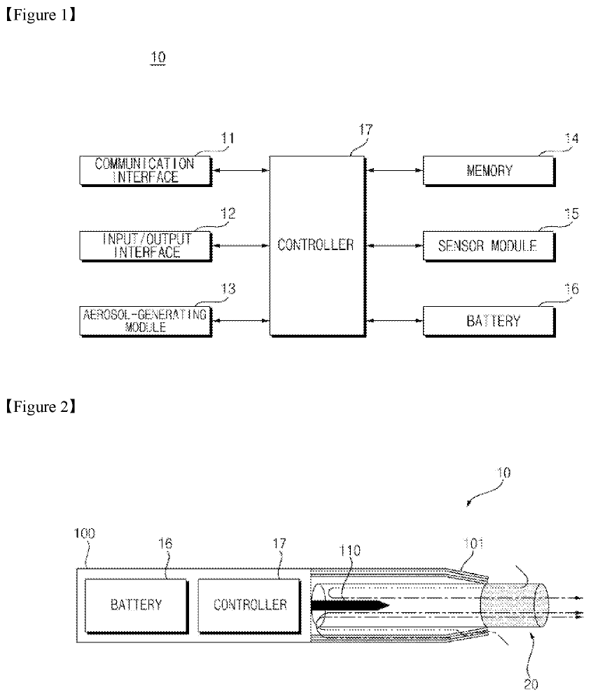

FIG. 1 is a block diagram of an aerosol-generating device according to an embodiment of the present disclosure.

Referring to FIG. 1, an aerosol-generating device 10 may include a communication interface 11, an input/output interface 12, an aerosol-generating module 13, a memory 14, a sensor module 15, a battery 16, and/or a controller 17.

In one embodiment, the aerosol-generating device 10 may be composed only of a main body. In this case, components included in the aerosol-generating device 10 may be located in the main body. In another embodiment, the aerosol-generating device 10 may be composed of a cartridge, which contains an aerosol-generating substance, and a main body. In this case, the components included in the aerosol-generating device 10 may be located in at least one of the main body or the cartridge.

The communication interface 11 may include at least one communication module for communication with an external device and/or a network. For example, the communication interface 11 may include a communication module for wired communication, such as a Universal Serial Bus (USB). For example, the communication interface 11 may include a communication module for wireless communication, such as Wireless Fidelity (Wi-Fi), Bluetooth, Bluetooth Low Energy (BLE), ZigBee, or nearfield communication (NFC).

The input/output interface 12 may include an input device (not shown) for receiving a command from a user and/or an output device (not shown) for outputting information to the user. For example, the input device may include a touch panel, a physical button, a microphone, or the like. For example, the output device may include a display device for outputting visual information, such as a display or a light-emitting diode (LED), an audio device for outputting auditory information, such as a speaker or a buzzer, a motor for outputting tactile information such as haptic effect, or the like.

The input/output interface 12 may transmit data corresponding to a command input by the user through the input device to another component (or other components) of the aerosol-generating device 100. The input/output interface 12 may output information corresponding to data received from another component (or other components) of the aerosol-generating device 10 through the output device.

The aerosol-generating module 13 may generate an aerosol from an aerosol-generating substance. Here, the aerosol-generating substance may be a substance in a liquid state, a solid state, or a gel state, which is capable of generating an aerosol, or a combination of two or more aerosol-generating substances.

According to an embodiment, the liquid aerosol-generating substance may be a liquid including a tobacco-containing material having a volatile tobacco flavor component. According to another embodiment, the liquid aerosol-generating substance may be a liquid including a non-tobacco material. For example, the liquid aerosol-generating substance may include water, solvents, nicotine, plant extracts, flavorings, flavoring agents, vitamin mixtures, etc.

The solid aerosol-generating substance may include a solid material based on a tobacco raw material such as a reconstituted tobacco sheet, shredded tobacco, or granulated tobacco. In addition, the solid aerosol-generating substance may include a solid material having a taste control agent and a flavoring material. For example, the taste control agent may include calcium carbonate, sodium bicarbonate, calcium oxide, etc. For example, the flavoring material may include a natural material such as herbal granules, or may include a material such as silica, zeolite, or dextrin, which includes an aroma ingredient.

In addition, the aerosol-generating substance may further include an aerosol-forming agent such as glycerin or propylene glycol.

The aerosol-generating module 13 may include at least one heater (not shown).

The aerosol-generating module 13 may include an electro-resistive heater. For example, the electro-resistive heater may include at least one electrically conductive track. The electro-resistive heater may be heated as current flows through the electrically conductive track. At this time, the aerosol-generating substance may be heated by the heated electro-resistive heater.

The electrically conductive track may include an electro-resistive material. In one example, the electrically conductive track may be formed of a metal material. In another example, the electrically conductive track may be formed of a ceramic material, carbon, a metal alloy, or a composite of a ceramic material and metal.

The electro-resistive heater may include an electrically conductive track that is formed in any of various shapes. For example, the electrically conductive track may be formed in any one of a tubular shape, a plate shape, a needle shape, a rod shape, and a coil shape.

The aerosol-generating module 13 may include a heater that uses an induction-heating method. For example, the induction heater may include an electrically conductive coil. The induction heater may generate an alternating magnetic field, which periodically changes in direction, by adjusting the current flowing through the electrically conductive coil. At this time, when the alternating magnetic field is applied to a magnetic body, energy loss may occur in the magnetic body due to eddy current loss and hysteresis loss. In addition, the lost energy may be released as thermal energy. Accordingly, the aerosol-generating substance located adjacent to the magnetic body may be heated. Here, an object that generates heat due to the magnetic field may be referred to as a susceptor.

Meanwhile, the aerosol-generating module 13 may generate ultrasonic vibrations to thereby generate an aerosol from the aerosol-generating substance.

The aerosol-generating device 10 may be referred to as a cartomizer, an atomizer, or a vaporizer.

The memory 14 may store programs for processing and controlling each signal in the controller 17. The memory 14 may store processed data and data to be processed.

For example, the memory 14 may store applications designed for the purpose of performing various tasks that can be processed by the controller 17. The memory 14 may selectively provide some of the stored applications in response to the request from the controller 17.

For example, the memory 14 may store data on the operation time of the aerosol-generating device 100, the maximum number of puffs, the current number of puffs, the number of uses of battery 16, at least one temperature profile, the user's inhalation pattern, and data about charging/discharging. Here, “puff” means inhalation by the user. “inhalation” means the user's act of taking air or other substances into the user's oral cavity, nasal cavity, or lungs through the user's mouth or nose.

The memory 14 may include at least one of volatile memory (e.g. dynamic random access memory (DRAM), static random access memory (SRAM), or synchronous dynamic random access memory (SDRAM)), nonvolatile memory (e.g. flash memory), a hard disk drive (HDD), or a solid-state drive (SSD).

The sensor module 15 may include at least one sensor.

For example, the sensor module 15 may include a sensor for sensing a puff (hereinafter referred to as a “puff sensor”). In this case, the puff sensor may be implemented as a proximity sensor such as an IR sensor, a pressure sensor, a gyro sensor, an acceleration sensor, a magnetic field sensor, or the like.

For example, the sensor module 15 may include a sensor for sensing a puff (hereinafter referred to as a “puff sensor”). In this case, the puff sensor may be implemented by a pressure sensor, a gyro sensor, an acceleration sensor, a magnetic field sensor, or the like.

For example, the sensor module 15 may include a sensor for sensing the temperature of the heater included in the aerosol-generating module 13 and the temperature of the aerosol-generating substance (hereinafter referred to as a “temperature sensor”). In this case, the heater included in the aerosol-generating module 13 may also serve as the temperature sensor. For example, the electro-resistive material of the heater may be a material having a predetermined temperature coefficient of resistance. The sensor module 15 may measure the resistance of the heater, which varies according to the temperature, to thereby sense the temperature of the heater.

For example, in the case in which the main body of the aerosol-generating device 10 is formed to allow a stick to be inserted thereinto, the sensor module 15 may include a sensor for sensing insertion of the stick (hereinafter referred to as a “stick detection sensor”).

For example, in the case in which the aerosol-generating device 10 includes a cartridge, the sensor module 15 may include a sensor for sensing mounting/demounting of the cartridge and the position of the cartridge (hereinafter referred to as a “cartridge detection sensor”).

In this case, the stick detection sensor and/or the cartridge detection sensor may be implemented as an inductance-based sensor, a capacitive sensor, a resistance sensor, or a Hall sensor (or Hall IC) using a Hall effect.

For example, the sensor module 15 may include a voltage sensor for sensing a voltage applied to a component (e.g. the battery 16) provided in the aerosol-generating device 10 and/or a current sensor for sensing a current.

The battery 16 may supply electric power used for the operation of the aerosol-generating device 10 under the control of the controller 17. The battery 16 may supply electric power to other components provided in the aerosol-generating device 100. For example, the battery 16 may supply electric power to the communication module included in the communication interface 11, the output device included in the input/output interface 12, and the heater included in the aerosol-generating module 13.

The battery 16 may be a rechargeable battery or a disposable battery. For example, the battery 16 may be a lithium-ion (Li-ion) battery or a lithium polymer (Li-polymer) battery. However, the present disclosure is not limited thereto. For example, when the battery 16 is rechargeable, the charging rate (C-rate) of the battery 16 may be 10C, and the discharging rate (C-rate) thereof may be 10C to 20C. However, the present disclosure is not limited thereto. Also, for stable use, the battery 16 may be manufactured such that 80% or more of the total capacity may be ensured even when charging/discharging is performed 2000 times.

The aerosol-generating device 10 may further include a protection circuit module (PCM) (not shown), which is a circuit for protecting the battery 16. The protection circuit module (PCM) may be disposed adjacent to the upper surface of the battery 16. For example, in order to prevent overcharging and overdischarging of the battery 16, the protection circuit module (PCM) may cut off the electrical path to the battery 16 when a short circuit occurs in a circuit connected to the battery 16, when an overvoltage is applied to the battery 16, or when an overcurrent flows through the battery 16.

The aerosol-generating device 10 may further include a charging terminal to which electric power supplied from the outside is input. For example, the charging terminal may be formed at one side of the main body of the aerosol-generating device 100. The aerosol-generating device 10 may charge the battery 16 using electric power supplied through the charging terminal. In this case, the charging terminal may be configured as a wired terminal for USB communication, a pogo pin, or the like.

The aerosol-generating device 10 may further include a power terminal (not shown) to which electric power supplied from the outside is input. For example, a power line may be connected to the power terminal, which is disposed at one side of the main body of the aerosol-generating device 100. The aerosol-generating device 10 may use the electric power supplied through the power line connected to the power terminal to charge the battery 16. In this case, the power terminal may be a wired terminal for USB communication.

The aerosol-generating device 10 may wirelessly receive electric power supplied from the outside through the communication interface 11. For example, the aerosol-generating device 10 may wirelessly receive electric power using an antenna included in the communication module for wireless communication. The aerosol-generating device 10 may charge the battery 16 using the wirelessly supplied electric power.

The controller 17 may control the overall operation of the aerosol-generating device 100. The controller 17 may be connected to each of the components provided in the aerosol-generating device 100. The controller 17 may transmit and/or receive a signal to and/or from each of the components, thereby controlling the overall operation of each of the components.

The controller 17 may include at least one processor. The controller 17 may control the overall operation of the aerosol-generating device 10 using the processor included therein. Here, the processor may be a general processor such as a central processing unit (CPU). Of course, the processor may be a dedicated device such as an application-specific integrated circuit (ASIC), or may be any of other hardware-based processors.

The controller 17 may perform any one of a plurality of functions of the aerosol-generating device 100. For example, the controller 17 may perform any one of a plurality of functions of the aerosol-generating device 10 (e.g. a preheating function, a heating function, a charging function, and a cleaning function) according to the state of each of the components provided in the aerosol-generating device 10 and the user's command received through the input/output interface 12.

The controller 17 may control the operation of each of the components provided in the aerosol-generating device 10 based on data stored in the memory 14. For example, the controller 17 may control the supply of a predetermined amount of electric power from the battery 16 to the aerosol-generating module 13 for a predetermined time based on the data on the temperature profile, the user's inhalation pattern, which is stored in the memory 14.

The controller 17 may determine the occurrence or non-occurrence of a puff using the puff sensor included in the sensor module 15. For example, the controller 17 may check a temperature change, a flow change, a pressure change, and a voltage change in the aerosol-generating device 10 based on the values sensed by the puff sensor. The controller 17 may determine the occurrence or non-occurrence of a puff based on the value sensed by the puff sensor.

The controller 17 may control the operation of each of the components provided in the aerosol-generating device 10 according to the occurrence or non-occurrence of a puff and/or the number of puffs. For example, the controller 17 may perform control such that the temperature of the heater is changed or maintained based on the temperature profile stored in the memory 14.

The controller 17 may perform control such that the supply of electric power to the heater is interrupted according to a predetermined condition. For example, the controller 17 may perform control such that the supply of electric power to the heater is interrupted when the stick is removed, when the cartridge is demounted, when the number of puffs reaches the predetermined maximum number of puffs, when a puff is not sensed during a predetermined period of time or longer, or when the remaining capacity of the battery 16 is less than a predetermined value.

The controller 17 may calculate the remaining capacity with respect to the full charge capacity of the battery 16. For example, the controller 17 may calculate the remaining capacity of the battery 16 based on the values sensed by the voltage sensor and/or the current sensor included in the sensor module 15.

The controller 17 may perform control such that electric power is supplied to the heater using at least one of a pulse width modulation (PWM) method or a proportional-integral-differential (PID) method.

For example, the controller 17 may perform control such that a current pulse having a predetermined frequency and a predetermined duty ratio is supplied to the heater using the PWM method. In this case, the controller 17 may control the amount of electric power supplied to the heater by adjusting the frequency and the duty ratio of the current pulse.

For example, the controller 17 may determine a target temperature to be controlled based on the temperature profile. In this case, the controller 17 may control the amount of electric power supplied to the heater using the PID method, which is a feedback control method using a difference value between the temperature of the heater and the target temperature, a value obtained by integrating the difference value with respect to time, and a value obtained by differentiating the difference value with respect to time.

Although the PWM method and the PID method are described as examples of methods of controlling the supply of electric power to the heater, the present disclosure is not limited thereto, and may employ any of various control methods, such as a proportional-integral (PI) method or a proportional-differential (PD) method.

Meanwhile, the controller 17 may perform control such that electric power is supplied to the heater according to a predetermined condition. For example, when a cleaning function for cleaning the space into which the stick is inserted is selected in response to a command input by the user through the input/output interface 12, the controller 17 may perform control such that a predetermined amount of electric power is supplied to the heater.

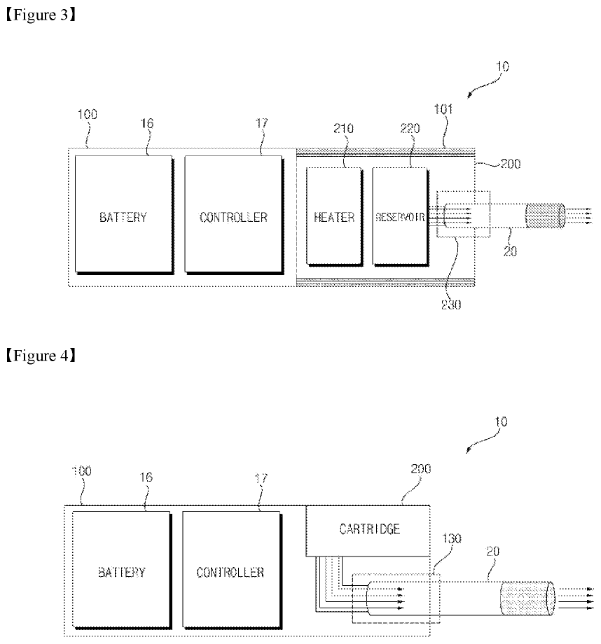

FIGS. 2 to 4 are views for explaining an aerosol-generating device according to embodiments of the present disclosure.

According to various embodiments of the present disclosure, the aerosol-generating device 10 may include a main body 100 and/or a cartridge 200.

Referring to FIG. 2, the aerosol-generating device 10 according to an embodiment may include a main body 100, which is formed such that a stick 20 can be inserted into the inner space formed by a housing 101.

The stick 20 may be similar to a general combustive cigarette. For example, the stick 20 may be divided into a first portion including an aerosol generating material and a second portion including a filter and the like. Alternatively, an aerosol generating material may be included in the second portion of the stick 20. For example, a flavoring substance made in the form of granules or capsules may be inserted into the second portion.

The entire first portion is inserted into the insertion space of the aerosol-generating device 10, and the second portion may be exposed to the outside. Alternatively, only a portion of the first portion may be inserted into the insertion space of the aerosol-generating device 10, or a portion of the first portion and the second portion may be inserted. In this case, the aerosol may be generated by passing external air through the first portion, and the generated aerosol may be delivered to the user's mouth through the second portion.

The main body 100 may be structured such that external air is introduced into the main body 100 in the state in which the stick 20 is inserted thereinto. In this case, the external air introduced into the main body 100 may flow into the mouth of the user via the stick 20.

The heater may be disposed in the main body 100 at a position corresponding to the position at which the stick 20 is inserted into the main body 100. Although it is illustrated in the drawings that the heater is an electrically conductive heater 110 including a needle-shaped electrically conductive track, the present disclosure is not limited thereto.

The heater may heat the interior and/or exterior of the stick 20 using the electric power supplied from the battery 16. An aerosol may be generated from the heated stick 20. At this time, the user may hold one end of the stick 20 in the mouth to inhale the aerosol containing a tobacco material.

Meanwhile, the controller 17 may perform control such that electric power is supplied to the heater in the state in which the stick 20 is not inserted into the main body according to a predetermined condition. For example, when a cleaning function for cleaning the space into which the stick 20 is inserted is selected in response to a command input by the user through the input/output interface 12, the controller 17 may perform control such that a predetermined amount of electric power is supplied to the heater.

The controller 17 may monitor the number of puffs based on the value sensed by the puff sensor from the point in time at which the stick 20 was inserted into the main body.

When the stick 20 is removed from the main body, the controller 17 may initialize the current number of puffs stored in the memory 14.

Referring to FIG. 3, the aerosol-generating device 10 according to an embodiment may include a main body 100 and a cartridge 200. The main body 100 may support the cartridge 200, and the cartridge 200 may contain an aerosol-generating substance.

According to one embodiment, the cartridge 200 may be configured so as to be detachably mounted to the main body 100. According to another embodiment, the cartridge 200 may be integrally configured with the main body 100. For example, the cartridge 200 may be mounted to the main body 100 in a manner such that at least a portion of the cartridge 200 is inserted into the insertion space formed by a housing 101 of the main body 100.

The main body 100 may be formed to have a structure in which external air can be introduced into the main body 100 in the state in which the cartridge 200 is inserted thereinto. Here, the external air introduced into the main body 100 may flow into the user's mouth via the cartridge 200.

The controller 17 may determine whether the cartridge 200 is in a mounted state or a detached state using a cartridge detection sensor included in the sensor module 15. For example, the cartridge detection sensor may transmit a pulse current through a first terminal connected with the cartridge 200. In this case, the controller 17 may determine whether the cartridge 200 is in a connected state, based on whether the pulse current is received through a second terminal.

The cartridge 200 may include a heater 210 configured to heat the aerosol-generating substance and/or a reservoir 220 configured to contain the aerosol-generating substance. The reservoir 220 may be referred to as a chamber. For example, a liquid delivery element impregnated with (containing) the aerosol-generating substance may be disposed inside the reservoir 220. The electrically conductive track of the heater 210 may be formed in a structure that is wound around the liquid delivery element. In this case, when the liquid delivery element is heated by the heater 210, an aerosol may be generated. Here, the liquid delivery element may include a wick made of, for example, cotton fiber, ceramic fiber, glass fiber, or porous ceramic.

The cartridge 200 may include an insertion space 230 configured to allow the stick 20 to be inserted. For example, the cartridge 200 may include the insertion space formed by an inner wall extending in a circumferential direction along a direction in which the stick 20 is inserted. In this case, the insertion space may be formed by opening the inner side of the inner wall up and down. The stick 20 may be inserted into the insertion space formed by the inner wall.

The insertion space into which the stick 20 is inserted may be formed in a shape corresponding to the shape of a portion of the stick 20 inserted into the insertion space. For example, when the stick 20 is formed in a cylindrical shape, the insertion space may be formed in a cylindrical shape.

When the stick 20 is inserted into the insertion space, the outer surface of the stick 20 may be surrounded by the inner wall and contact the inner wall.

A portion of the stick 20 may be inserted into the insertion space, the remaining portion of the stick 20 may be exposed to the outside.

The user may inhale the aerosol while biting one end of the stick 20 with the mouth. The aerosol generated by the heater 210 may pass through the stick 20 and be delivered to the user's mouth. At this time, while the aerosol passes through the stick 20, the material contained in the stick 20 may be added to the aerosol. The material-infused aerosol may be inhaled into the user's oral cavity through the one end of the stick 20.

Referring to FIG. 4, the aerosol-generating device 10 according to an embodiment may include a main body 100 supporting the cartridge 200 and a cartridge 200 containing an aerosol-generating substance. The main body 100 may be formed so as to allow the stick 20 to be inserted into an insertion space 1300 therein.

The aerosol-generating device 10 may include a first heater for heating the aerosol-generating substance stored in the cartridge 200. For example, when the user holds one end of the stick 20 in the mouth to inhale the aerosol, the aerosol generated by the first heater may pass through the stick 20. At this time, while the aerosol passes through the stick 20, a flavor may be added to the aerosol. The aerosol containing the flavor may be drawn into the user's oral cavity through one end of the stick 20.

Alternatively, according to another embodiment, the aerosol-generating device 10 may include a first heater for heating the aerosol-generating substance stored in the cartridge 200 and a second heater for heating the stick 20 inserted into the main body 100. For example, the aerosol-generating device 10 may generate an aerosol by heating the aerosol-generating substance stored in the cartridge 200 and the stick 20 using the first heater and the second heater, respectively.

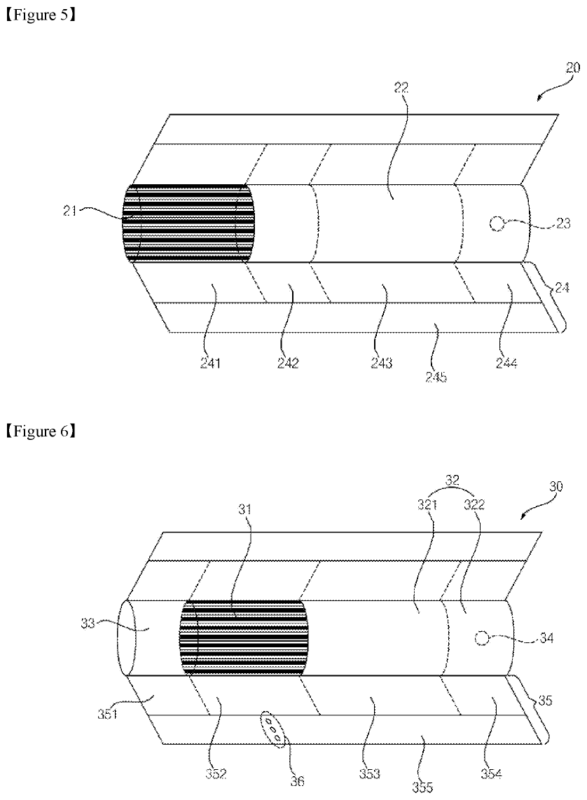

FIGS. 5 and 6 are views for explaining a stick according to embodiments of the present disclosure.

Referring to FIG. 5, the stick 20 may include a tobacco rod 21 and a filter rod 22. The first portion described above with reference to FIG. 2 may include the tobacco rod. The second portion described above with reference to FIG. 2 may include the filter rod 22.

FIG. 5 illustrates that the filter rod 22 includes a single segment. However, the filter rod 22 is not limited thereto. In other words, the filter rod 22 may include a plurality of segments. For example, the filter rod 22 may include a first segment configured to cool an aerosol and a second segment configured to filter a certain component included in the aerosol. Also, as necessary, the filter rod 22 may further include at least one segment configured to perform other functions.

A diameter of the stick 20 may be within a range of 5 mm to 9 mm, and a length of the stick 20 may be about 48 mm, but embodiments are not limited thereto. For example, a length of the tobacco rod 21 may be about 12 mm, a length of a first segment of the filter rod 22 may be about 10 mm, a length of a second segment of the filter rod 22 may be about 14 mm, and a length of a third segment of the filter rod 22 may be about 12 mm, but embodiments are not limited thereto.

The stick 20 may be wrapped using at least one wrapper 24. The wrapper 24 may have at least one hole through which external air may be introduced or internal air may be discharged. For example, the stick 20 may be wrapped using one wrapper 24. As another example, the stick 20 may be double-wrapped using at least two wrappers 24. For example, the tobacco rod 21 may be wrapped using a first wrapper 241. For example, the filter rod 22 may be wrapped using wrappers 242, 243, 244. The tobacco rod 21 and the filter rod 22 wrapped by wrappers may be combined. The stick 20 may be re-wrapped by a single wrapper 245. When each of the tobacco rod 21 and the filter rod 22 includes a plurality of segments, each segment may be wrapped using wrappers 242, 243, 244. The entirety of stick 20 composed of a plurality of segments wrapped by wrappers may be re-wrapped by another wrapper

The first wrapper 241 and the second wrapper 242 may be formed of general filter wrapping paper. For example, the first wrapper 241 and the second wrapper 242 may be porous wrapping paper or non-porous wrapping paper. Also, the first wrapper 241 and the second wrapper 242 may be made of an oil-resistant paper sheet and an aluminum laminate packaging material.

The third wrapper 243 may be made of a hard wrapping paper. For example, a basis weight of the third wrapper 243 may be within a range of 88 g/m2 to 96 g/m2. For example, the basis weight of the third wrapper 243 may be within a range of 90 g/m2 to 94 g/m2. Also, a total thickness of the third wrapper 243 may be within a range of 1200 μm to 1300 μm. For example, the total thickness of the third wrapper 243 may be 125 μm.

The fourth wrapper 244 may be made of an oil-resistant hard wrapping paper. For example, a basis weight of the fourth wrapper 244 may be within a range of about 88 g/m2 to about 96 g/m2. For example, the basis weight of the fourth wrapper 244 may be within a range of 90 g/m2 to 94 g/m2. Also, a total thickness of the fourth wrapper 244 may be within a range of 1200 μm to 1300 μm. For example, the total thickness of the fourth wrapper 244 may be 125 μm.

The fifth wrapper 245 may be made of a sterilized paper (MFW). Here, the MFW refers to a paper specially manufactured to have enhanced tensile strength, water resistance, smoothness, and the like, compared to ordinary paper. For example, a basis weight of the fifth wrapper 245 may be within a range of 57 g/m2 to 63 g/m2. For example, a basis weight of the fifth wrapper 245 may be about 60 g/m2. Also, the total thickness of the fifth wrapper 245 may be within a range of 64 μm to 70 μm. For example, the total thickness of the fifth wrapper 245 may be 67 μm.

A predetermined material may be included in the fifth wrapper 245. Here, an example of the predetermined material may be, but is not limited to, silicon. For example, silicon exhibits characteristics like heat resistance with little change due to the temperature, oxidation resistance, resistances to various chemicals, water repellency, electrical insulation, etc. However, any material other than silicon may be applied to (or coated on) the fifth wrapper 245 without limitation as long as the material has the above-mentioned characteristics.

The fifth wrapper 245 may prevent the stick 20 from being burned. For example, when the tobacco rod 21 is heated by the heater 110, there is a possibility that the stick 20 is burned. In detail, when the temperature is raised to a temperature above the ignition point of any one of materials included in the tobacco rod 21, the stick 20 may be burned. Even in this case, since the fifth wrapper 245 include a non-combustible material, the burning of the stick 20 may be prevented.

Furthermore, the fifth wrapper 245 may prevent the aerosol generating device 100 from being contaminated by substances formed by the stick 20. Through puffs of a user, liquid substances may be formed in the stick 20. For example, as the aerosol formed by the stick 20 is cooled by the outside air, liquid materials (e.g., moisture, etc.) may be formed. As the fifth wrapper 245 wraps the stick 20, the liquid materials formed in the stick 20 may be prevented from being leaked out of the stick 20.

The tobacco rod 21 may include an aerosol generating material. For example, the aerosol generating material may include at least one of glycerin, propylene glycol, ethylene glycol, dipropylene glycol, diethylene glycol, triethylene glycol, tetraethylene glycol, and oleyl alcohol, but it is not limited thereto. Also, the tobacco rod 21 may include other additives, such as flavors, a wetting agent, and/or organic acid. Also, the tobacco rod 21 may include a flavored liquid, such as menthol or a moisturizer, which is injected to the tobacco rod 21.

The tobacco rod 21 may be manufactured in various forms. For example, the tobacco rod 21 may be formed as a sheet or a strand. Also, the tobacco rod 21 may be formed as a pipe tobacco, which is formed of tiny bits cut from a tobacco sheet. Also, the tobacco rod 21 may be surrounded by a heat conductive material. For example, the heat-conducting material may be, but is not limited to, a metal foil such as aluminum foil. For example, the heat conductive material surrounding the tobacco rod 21 may uniformly distribute heat transmitted to the tobacco rod 21, and thus, the heat conductivity applied to the tobacco rod may be increased and taste of the tobacco may be improved. Also, the heat conductive material surrounding the tobacco rod 21 may function as a susceptor heated by the induction heater. Here, although not illustrated in the drawings, the tobacco rod 21 may further include an additional susceptor, in addition to the heat conductive material surrounding the tobacco rod 21.

The filter rod 22 may include a cellulose acetate filter. Shapes of the filter rod 22 are not limited. For example, the filter rod 22 may include a cylinder-type rod or a tube-type rod having a hollow inside. Also, the filter rod 22 may include a recess-type rod. When the filter rod 22 includes a plurality of segments, at least one of the plurality of segments may have a different shape.

The first segment of the filter rod 22 may be a cellulous acetate filter. For example, the first segment may be a tube-type structure having a hollow inside. The first segment may prevent an internal material of the tobacco rod 21 from being pushed back when the heater 110 is inserted into the tobacco rod 21 and may also provide a cooling effect to aerosol. A diameter of the hollow included in the first segment may be an appropriate diameter within a range of 2 mm to 4.5 mm but is not limited thereto.

The length of the first segment may be an appropriate length within a range of 4 mm to 30 mm but is not limited thereto. For example, the length of the first segment may be 10 mm but is not limited thereto.

The second segment of the filter rod 22 cools the aerosol which is generated when the heater 110 heats the tobacco rod 21. Therefore, the user may puff the aerosol which is cooled at an appropriate temperature.

The length or diameter of the second segment may be variously determined according to the shape of the stick 20. For example, the length of the second segment may be an appropriate length within a range of 7 mm to 20 mm. Preferably, the length of the second segment may be about 14 mm but is not limited thereto.

The second segment may be manufactured by weaving a polymer fiber. In this case, a flavoring liquid may also be applied to the fiber formed of the polymer. Alternatively, the second segment may be manufactured by weaving together an additional fiber coated with a flavoring liquid and a fiber formed of a polymer. Alternatively, the second segment may be formed by a crimped polymer sheet.

For example, a polymer may be formed of a material selected from the group consisting of polyethylene (PE), polypropylene (PP), polyvinyl chloride (PVC), polyethylene terephthalate (PET), polylactic acid (PLA), cellulous acetate (CA), and aluminum coil.

As the second segment is formed by the woven polymer fiber or the crimped polymer sheet, the second segment may include a single channel or a plurality of channels extending in a longitudinal direction. Here, a channel refers to a passage through which a gas (e.g., air or aerosol) passes.

For example, the second segment formed of the crimped polymer sheet may be formed from a material having a thickness between about 5 μm and about 300 μm, for example, between about 10 μm and about 250 μm. Also, a total surface area of the second segment may be between about 300 mm2/mm and about 1000 mm2/mm. In addition, an aerosol cooling element may be formed from a material having a specific surface area between about 10 mm2/mg and about 100 mm2/mg.

The second segment may include a thread including a volatile flavor component. Here, the volatile flavor component may be menthol but is not limited thereto. For example, the thread may be filled with a sufficient amount of menthol to provide the second segment with menthol of 1.5 mg or more.

The third segment of the filter rod 22 may be a cellulous acetate filter. The length of the third segment may be an appropriate length within a range of 4 mm to 20 mm. For example, the length of the third segment may be about 12 mm but is not limited thereto.

The filter rod 22 may be manufactured to generate flavors. For example, a flavoring liquid may be injected onto the filter rod 22. For example, an additional fiber coated with a flavoring liquid may be inserted into the filter rod 22.

Also, the filter rod 22 may include at least one capsule 23. Here, the capsule 23 may generate a flavor. The capsule 23 may generate an aerosol. For example, the capsule 23 may have a configuration in which a liquid including a flavoring material is wrapped with a film. The capsule 23 may have a spherical or cylindrical shape but is not limited thereto.

Referring to FIG. 6, a stick 30 may further include a front-end plug 33. The front-end plug 33 may be located on a side of a tobacco rod 31, the side not facing a filter rod 32. The front-end plug 33 may prevent the tobacco rod 31 from being detached and prevent liquefied aerosol from flowing into the aerosol generating device 10 from the tobacco rod 31, during smoking.

The filter rod 32 may include a first segment 321 and a second segment 322. The first segment 321 may correspond to the first segment of the filter rod 22 of FIG. 4. The segment 322 may correspond to the third segment of the filter rod 22 of FIG. 4.

A diameter and a total length of the stick 30 may correspond to the diameter and a total length of the stick 20 of FIG. 4. For example, a length of the front-end plug 33 may be about 7 mm, a length of the tobacco rod 31 may be about 15 mm, a length of the first segment 321 may be about 12 mm, and a length of the second segment 322 may be about 14 mm, but embodiments are not limited thereto.

The stick 30 may be wrapped using at least one wrapper 35. The wrapper 35 may have at least one hole through which external air may be introduced or internal air may be discharged. For example, the front-end plug 33 may be wrapped using a first wrapper 351, the tobacco rod 31 may be wrapped using a second wrapper 352, the first segment 321 may be wrapped using a third wrapper 353, and the second segment 322 may be wrapped using a fourth wrapper 354. Also, the entire stick 30 may be re-wrapped using a fifth wrapper 355.

In addition, the fifth wrapper 355 may have at least one perforation 36 formed therein. For example, the perforation 36 may be formed in an area of the fifth wrapper 355 surrounding the tobacco rod 31 but is not limited thereto. For example, the perforation 36 may transfer heat formed by the heater 210 illustrated in FIG. 3 into the tobacco rod 31.

Also, the second segment 322 may include at least one capsule 34. Here, the capsule 34 may generate a flavor. The capsule 34 may generate an aerosol. For example, the capsule 34 may have a configuration in which a liquid including a flavoring material is wrapped with a film. The capsule 34 may have a spherical or cylindrical shape but is not limited thereto.

The first wrapper 351 may be formed by combining general filter wrapping paper with a metal foil such as an aluminum coil. For example, a total thickness of the first wrapper 351 may be within a range of 45 μm to 55 μm. For example, the total thickness of the first wrapper 351 may be 50.3 μm. Also, a thickness of the metal coil of the first wrapper 351 may be within a range 6 μm to 7 μm. For example, the thickness of the metal coil of the first wrapper 351 may be 6.3 μm. In addition, a basis weight of the first wrapper 351 may be within a range of 50 g/m2 to 55 g/m2. For example, the basis weight of the first wrapper 351 may be 53 g/m2.

The second wrapper 352 and the third wrapper 353 may be formed of general filter wrapping paper. For example, the second wrapper 352 and the third wrapper 353 may be porous wrapping paper or non-porous wrapping paper.

For example, porosity of the second wrapper 352 may be 35000 CU but is not limited thereto. Also, a thickness of the second wrapper 352 may be within a range of 70 μm to 80 μm. For example, the thickness of the second wrapper 352 may be 78 μm. A basis weight of the second wrapper 352 may be within a range of 20 g/m2 to 25 g/m2. For example, the basis weight of the second wrapper 352 may be 23.5 g/m2.

For example, porosity of the third wrapper 353 may be 24000 CU but is not limited thereto. Also, a thickness of the third wrapper 353 may be in a range of about 60 μm to about 70 μm. For example, the thickness of the third wrapper 353 may be 68 μm. A basis weight of the third wrapper 353 may be in a range of about 20 g/m2 to about 25 g/m2. For example, the basis weight of the third wrapper 353 may be 21 g/m2.

The fourth wrapper 354 may be formed of PLA laminated paper. Here, the PLA laminated paper refers to three-layer paper including a paper layer, a PLA layer, and a paper layer. For example, a thickness of the fourth wrapper 353 may be in a range of 100 μm to 1200 μm. For example, the thickness of the fourth wrapper 353 may be 110 μm. Also, a basis weight of the fourth wrapper 354 may be in a range of 80 g/m2 to 100 g/m2. For example, the basis weight of the fourth wrapper 354 may be 88 g/m2.

The fifth wrapper 355 may be formed of sterilized paper (MFW). Here, the sterilized paper (MFW) refers to paper which is particularly manufactured to improve tensile strength, water resistance, smoothness, and the like more than ordinary paper. For example, a basis weight of the fifth wrapper 355 may be in a range of 57 g/m2 to 63 g/m2. For example, the basis weight of the fifth wrapper 355 may be 60 g/m2. Also, a thickness of the fifth wrapper 355 may be in a range of 64 μm to 70 μm. For example, the thickness of the fifth wrapper 355 may be 67 μm.

The fifth wrapper 355 may include a preset material added thereto. An example of the material may include silicon, but it is not limited thereto. Silicon has characteristics such as heat resistance robust to temperature conditions, oxidation resistance, resistance to various chemicals, water repellency to water, and electrical insulation, etc. Besides silicon, any other materials having characteristics as described above may be applied to (or coated on) the fifth wrapper 355 without limitation.

The front-end plug 33 may be formed of cellulous acetate. For example, the front-end plug 33 may be formed by adding a plasticizer (e.g., triacetin) to cellulous acetate tow. Mono-denier of filaments constituting the cellulous acetate tow may be in a range of 1.0 to 10.0. For example, the mono-denier of filaments constituting the cellulous acetate tow may be within a range of 4.0 to 6.0. For example, the mono-denier of the filaments of the front-end plug 33 may be 5.0. Also, a cross-section of the filaments constituting the front-end plug 33 may be a Y shape. Total denier of the front-end plug 33 may be in a range of 20000 to 30000. For example, the total denier of the front-end plug 33 may be within a range of 25000 to 30000. For example, the total denier of the front-end plug 33 may be 28000.

Also, as needed, the front-end plug 33 may include at least one channel. A cross-sectional shape of the channel may be manufactured in various shapes.

The tobacco rod 31 may correspond to the tobacco rod 21 described above with reference to FIG. 4. Therefore, hereinafter, the detailed description of the tobacco rod 31 will be omitted.

The first segment 321 may be formed of cellulous acetate. For example, the first segment 321 may be a tube-type structure having a hollow inside. The first segment 321 may be manufactured by adding a plasticizer (e.g., triacetin) to cellulous acetate tow. For example, mono-denier and total denier of the first segment 321 may be the same as the mono-denier and total denier of the front-end plug 33.

The second segment 322 may be formed of cellulous acetate. Mono denier of filaments constituting the second segment 322 may be in a range of 1.0 to 10.0. For example, the mono denier of the filaments of the second segment 322 may be within a range of about 8.0 to about 10.0. For example, the mono denier of the filaments of the second segment 322 may be 9.0. Also, a cross-section of the filaments of the second segment 322 may be a Y shape. Total denier of the second segment 322 may be in a range of 20000 to 30000. For example, the total denier of the second segment 322 may be 25000.

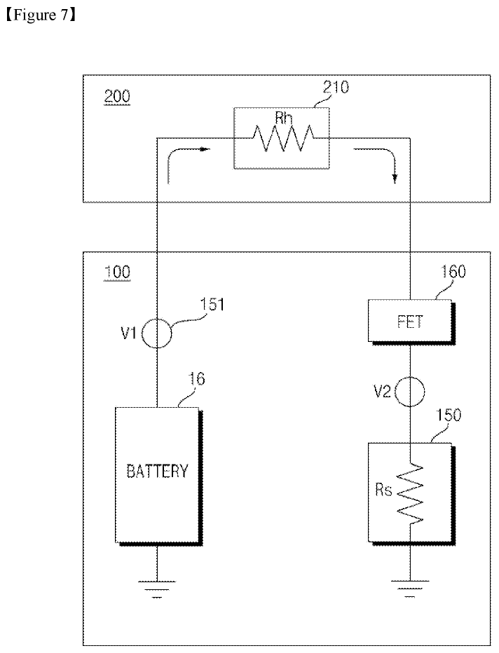

FIG. 7 is a diagram for explaining the configuration of an aerosol-generating device according to an embodiment of the present disclosure.

Referring to FIG. 7, an aerosol-generating device 10 may include a battery 16, a resistance detection sensor 150, a switching element 160, and/or a heater 210. The aerosol-generating device 10 may further include a voltage sensor 151 for detecting the voltage of the battery 16.

The battery 16, the resistance detection sensor 150, the switching element 160, and/or the voltage sensor 151 may be disposed in the main body 100. The heater 210 may be included in the cartridge 200.

The battery 16 may be electrically connected to the heater 210. The battery 16 may supply power to the heater 210. The heater 210 may heat a liquid-type aerosol-generating substance contained in the chamber 220 using the power supplied from the battery 16. For example, the heater 210 may heat a wick connected to the chamber 220.

The resistance detection sensor 150 may be electrically connected to the heater 210. The resistance detection sensor 150 may be electrically connected to the switching element 160. The resistance detection sensor 150 may be electrically connected to the heater 210 via the switching element 160. For example, the resistance detection sensor 150 may be electrically connected to the heater 210 when the switching element 160 is turned on.

The switching element 160 may be electrically connected to the heater 210. The present disclosure will be described on the assumption that the switching element 160 is a field effect transistor (FET), but the present disclosure is not limited thereto. For example, the switching element 160 may be implemented as a bipolar junction transistor (BJT) or a relay.

The controller 17 may control the operation of the switching element 160. For example, the controller 17 may adjust the voltage applied to the gate terminal of the switching element 160 to control on/off operation of the switching element 160. When the switching element 160 is turned on, power may be supplied to the heater 210 from the battery 16. When the switching element 160 is turned off, the supply of power to the heater 210 from the battery 16 may be interrupted.

The controller 17 may adjust the power supplied to the heater 210. The controller 17 may adjust the power supplied to the heater 210 through control based on a duty ratio. For example, the controller 17 may turn on/off the switching element 160 according to a duty ratio. In this case, as the duty ratio increases, the power supplied to the heater 210 may increase, and as the duty ratio decreases, the power supplied to the heater 210 may decrease.

The resistance detection sensor 150 may output a signal corresponding to the resistance of the heater 210 based on the voltage V2 applied to a shunt resistor. When the heater 210 and the resistance detection sensor 150 are electrically connected to each other via the switching element 160, current having the same magnitude may flow through the heater 210 and the resistance detection sensor 150. Here, the resistance Rs of the shunt resistor provided in the resistance detection sensor 150 may be a value that does not change with the temperature of the shunt resistor. Meanwhile, the resistor of the heater 210 may be a material having a temperature coefficient of resistance, and the resistance Rh of the heater 210 may vary depending on changes in the temperature of the resistor. Therefore, the voltage V2 applied to the shunt resistor of the resistance detection sensor 150 may vary depending on changes in the resistance Rh of the heater 210. For example, as the resistance Rh of the heater 210 increases, the voltage V2 applied to the shunt resistor of the resistance detection sensor 150 may decrease.

The controller 17 may calculate the current flowing through the heater 210 based on the resistance Rs of the shunt resistor and the voltage V2 applied to the shunt resistor. The controller 17 may calculate the resistance of the heater 210 based on the voltage V1 of the battery 16 calculated by the voltage sensor 151 and the voltage V2 applied to the shunt resistor. For example, the controller 17 may calculate the voltage applied to the heater 210 based on the difference (V1−V2) between the voltage V1 of the battery 16 and the voltage V2 applied to the shunt resistor. In this case, the voltage applied across both ends of the switching element 160 may be determined based on a resistance set for the switching element 160. The controller 17 may calculate the resistance Rh of the heater 210 based on the voltage applied to the heater 210 and the current flowing through the heater 210.

The controller 17 may calculate the temperature of the heater 210. For example, the controller 17 may calculate the temperature of the heater 210 based on the temperature coefficient of resistance of the heater 210, the resistance Rh of the heater 210, and the resistance of the heater 210 at a reference temperature. Here, the heater temperature calculation equation used to calculate the temperature of the heater 210 may be expressed using the following Equation 1.

$$T C R = ( R 1 - R 0 ) / R 0 \div ( T 1 - T 0 ) \qquad [ Equation 1 ]$$

In Equation 1 above, TCR represents the temperature coefficient of resistance of the heater 210, T1 represents the temperature of the heater 210, R1 represents the resistance of the heater 210, T0 represents the reference temperature, and R0 represents the resistance of the heater 210 at the reference temperature. Here, T0 is 25° C., and R0 is the resistance of the heater 210 at 25° C.

Although the present disclosure is described on the assumption that the current sensor connected in series to the heater 210 is the resistance detection sensor 150, the present disclosure is not limited thereto. A voltage sensor for detecting the voltage applied to the heater 210 may be provided as the resistance detection sensor 150.

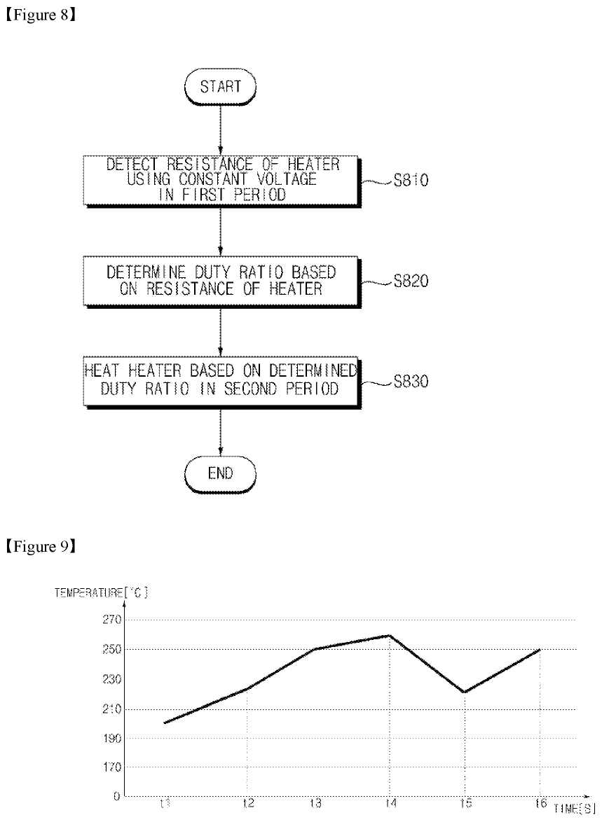

FIG. 8 is a flowchart showing an operation method of an aerosol-generating device according to an embodiment of the present disclosure.

Referring to FIG. 8, the aerosol-generating device 10 may detect the resistance of the heater 210 using constant voltage in a first period in which power is supplied to the heater 210 in operation S810.

According to an embodiment, the aerosol-generating device 10 may turn on the switching element 160 in the first period. While the switching element 160 is maintained in an on state, constant voltage corresponding to the voltage of the battery 16 may be constantly applied to the heater 210. In this case, the aerosol-generating device 10 may detect the resistance of the heater 210 based on the signal from the resistance detection sensor 150 while constant voltage corresponding to the voltage of the battery 16 is applied to the heater 210. Accordingly, power is continuously supplied to the heater 210 even while the resistance of the heater 210 is detected, and thus the temperature of the heater 210 may not decrease.

The aerosol-generating device 10 may determine a duty ratio based on the resistance of the heater 210 in operation S820. According to an embodiment, the aerosol-generating device 10 may calculate the temperature of the heater 210 based on the resistance of the heater 210. In this case, the aerosol-generating device 10 may determine the duty ratio based on the difference between the target temperature determined based on the temperature profile and the calculated temperature of the heater 210. For example, as the difference between the target temperature and the calculated temperature of the heater 210 increases, the duty ratio may increase.

The aerosol-generating device 10 may heat the heater 210 based on the duty ratio determined based on the resistance of the heater 210 in a second period after the first period, in which power is supplied to the heater 210, in operation S830. The aerosol-generating device 10 may turn on/off the switching element 160 according to the determined duty ratio. In this case, a current pulse having a duty ratio may flow through the heater 210 based on on/off of the switching element 160 according to the duty ratio. In this case, the power supplied to the heater 210 may correspond to the duty ratio of the current pulse flowing through the heater 210. The duty ratio of the current pulse flowing through the heater 210 may correspond to the duty ratio determined based on the resistance of the heater 210.

Meanwhile, the first period and the second period may be alternately repeated while power is supplied to the heater 210. For example, the second period may be started when the first period ends, and the first period may be started when the second period ends.

Meanwhile, a first time period corresponding to the first period may be shorter than a second time period corresponding to the second period. For example, the aerosol-generating device 10 may determine the duty ratio for 10 ms, which is the first time period corresponding to the first period, and may turn on/off the switching element 160 according to the duty ratio for 200 ms, which is the second time period corresponding to the second period.

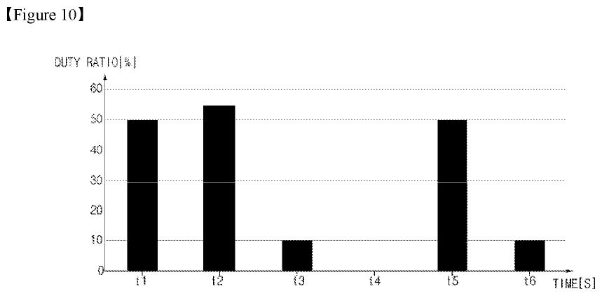

Referring to FIGS. 9 and 10, power may be supplied to the heater 210 from a time point t1 to a time point t2 according to a duty ratio determined to be 50% at the time point t1. In addition, the temperature of the heater 210 may increase in response to the duty ratio of 50% from the time point t1 to the time point t2.

Meanwhile, power may be supplied to the heater 210 from the time point t2 to a time point t3 according to the duty ratio increased to 60% at the time point t2. In addition, the temperature of the heater 210 may increase in response to the duty ratio of 60% from the time point t2 to the time point t3. In this case, a second temperature slope in the period from the time point t2 to the time point t3 may be greater than a first temperature slope in the period from the time point t1 to the time point t2. That is, as the duty ratio increases, the power supplied to the heater 210 may increase, and accordingly, the temperature of the heater 210 may increase more sharply.

Meanwhile, power may be supplied to the heater 210 from the time point t3 to a time point t4 according to the duty ratio decreased to 10% at the time point t3. In this case, a third temperature slope in the period from the time point t3 to the time point t4 may be less than the first temperature slope or the second temperature slope. That is, as the duty ratio decreases, the power supplied to the heater 210 may decrease, and accordingly, the temperature of the heater 210 may increase more gently.

Meanwhile, the supply of power to the heater 210 may be interrupted from the time point t4 to a time point t5 according to the duty ratio decreased to 0% at the time point t4. In this case, the temperature of the heater 210 may gradually decrease from the time point t4 to the time point t5. For example, when the calculated temperature of the heater 210 is equal to or higher than the target temperature determined based on the temperature profile, the duty ratio may be determined to be 0%.

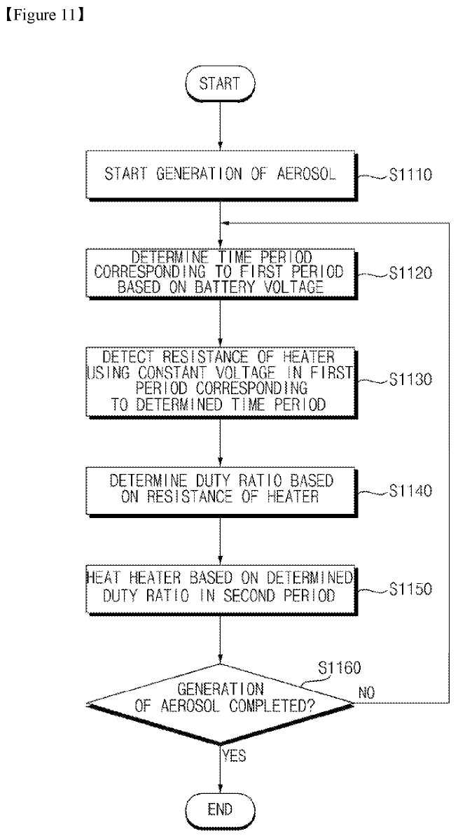

FIG. 11 is a flowchart showing an operation method of an aerosol-generating device according to another embodiment of the present disclosure. A detailed description of the same content as that described with reference to FIG. 8 will be omitted.

Referring to FIG. 11, the aerosol-generating device 10 may start generation of an aerosol in operation S1110. For example, the aerosol-generating device 10 may supply power to the heater 210 in response to insertion of the stick 20 into the insertion spaces 130 and 230 detected by the stick detection sensor. For example, the aerosol-generating device 10 may supply power to the heater 210 in response to detection of a puff by the puff sensor.

The aerosol-generating device 10 may determine a time period corresponding to the first period based on the voltage of the battery 16 checked by the voltage sensor 151 in operation S1120. In this case, the time period corresponding to the first period may be equal to or longer than the minimum time required for the controller 16 to determine the duty ratio based on the signal from the resistance detection sensor 150.

According to an embodiment, when the voltage of the battery 16 is equal to or higher than predetermined voltage, the aerosol-generating device 10 may determine the time period corresponding to the first period to be a time period set for detection of the resistance of the heater 210 (hereinafter referred to as a detection time period). When the voltage of the battery 16 is lower than the predetermined voltage, the aerosol-generating device 10 may determine the time period corresponding to the first period to be a time period shorter than the predetermined detection time period. In this case, when the voltage of the battery 16 is lower than the predetermined voltage, the time period corresponding to the first period may be determined in proportion to the voltage of the battery 16. That is, when the voltage of the battery 16 is lower than the predetermined voltage, the time period corresponding to the first period may be shortened as the voltage of the battery 16 decreases. Therefore, in the state in which the voltage of the battery 16 is lower than the predetermined voltage, overdischarge of the battery 16 may be minimized even while power is supplied to the heater 210 in response to turn-on of the switching element 150 in the first period.

Meanwhile, when the voltage of the battery 16 checked by the voltage sensor 151 is lower than predetermined minimum voltage, the supply of power to the heater 210 may be interrupted. Here, the minimum voltage may be a voltage value set for the case in which overdischarge of the battery 16 is highly likely to occur due to the supply of power to the heater 210.

The aerosol-generating device 10 may turn on the switching element 160 in the first period corresponding to the determined time period in operation S1130. In this case, the aerosol-generating device 10 may detect the resistance of the heater 210 based on the signal from the resistance detection sensor 150 while constant voltage corresponding to the voltage of the battery 16 is applied to the heater 210.

The aerosol-generating device 10 may determine a duty ratio based on the resistance of the heater 210 in operation S1140.

The aerosol-generating device 10 may heat the heater 210 based on the determined duty ratio in the second period after the first period, in which power is supplied to the heater 210, in operation S1150. Here, the time period corresponding to the second period may be a specific time period set for heating of the heater. In this case, the specific time period may be set to be longer than the predetermined detection time period.

The aerosol-generating device 10 may determine whether the generation of an aerosol is completed in operation S1160. For example, when the stick is removed, when the cartridge is separated, when the number of puffs reaches a predetermined maximum number of puffs, when no puff is detected for a predetermined time period or longer, or when the remaining charge of the battery 16 is less than a predetermined value, the aerosol-generating device 10 may terminate the generation of an aerosol.

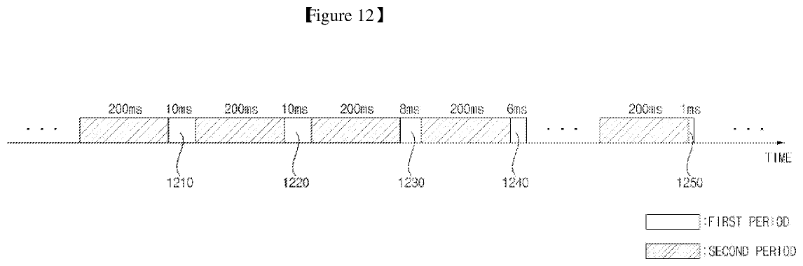

Referring to FIG. 12, the first period in which the switching element 160 is maintained in an on state and the second period in which the switching element 160 is turned on/off according to the duty ratio may be alternately repeated. In this case, the time period corresponding to the first period may be gradually shortened over time. That is, in the first periods 1210 and 1220 corresponding to the case in which the voltage of the battery 16 is equal to or higher than predetermined voltage, the switching element 160 may be maintained in an on state for 10 ms.

Meanwhile, in the first periods 1230, 1240, and 1250 corresponding to the case in which the voltage of the battery 16 is lower than the predetermined voltage, the time period for which the switching element 160 is maintained in an on state may be shortened as the voltage of the battery 16 decreases. In this case, the time period corresponding to the first period may be equal to or longer than 1 ms, which is the minimum time required for the controller 16 to determine the duty ratio based on the signal from the resistance detection sensor 150.

As described above, according to at least one of the embodiments of the present disclosure, it may be possible to accurately determine the resistance of the heater while the heater is heated.

In addition, according to at least one of the embodiments of the present disclosure, it may be possible to prevent the temperature of the heater from being lowered while the resistance of the heater is detected.

In addition, according to at least one of the embodiments of the present disclosure, it may be possible to minimize overdischarge of the battery while the heater is heated.

Referring to FIGS. 1 to 12, an aerosol-generating device 10 in accordance with one aspect of the present disclosure may include a heater 210 configured to heat an aerosol-generating substance, a battery 16 configured to supply power to the heater 210, a resistance detection sensor 150 configured to output a signal corresponding to the resistance of the heater 210, a switching element 160 electrically connected to the heater 210, and a controller 17 configured to control operation of the switching element 160. The controller 17 may perform control such that the switching element 160 is turned on in a first period in which power is supplied to the heater 210, may determine a duty ratio based on the resistance of the heater 210 corresponding to a signal from the resistance detection sensor 150 in the first period, and may adjust switching operation of the switching element 160 based on the determined duty ratio in a second period after the first period in which power is supplied to the heater 210.

In addition, in accordance with another aspect of the present disclosure, the first period and the second period may be alternately repeated while power is supplied to the heater 210.

In addition, in accordance with another aspect of the present disclosure, a first time period corresponding to the first period may be shorter than a second time period corresponding to the second period.

In addition, in accordance with another aspect of the present disclosure, the aerosol-generating device may further include a voltage sensor 151 configured to detect voltage of the battery 16. The controller 17 may determine a time period corresponding to the first period based on the voltage of the battery 16 detected by the voltage sensor 151.

In addition, in accordance with another aspect of the present disclosure, the time period corresponding to the first period may be equal to or longer than a minimum time required for the controller 17 to determine the duty ratio based on a signal from the resistance detection sensor 150.

In addition, in accordance with another aspect of the present disclosure, a time period corresponding to the second period may be a time period set for heating of the heater 210.

In addition, in accordance with another aspect of the present disclosure, the controller 17 may interrupt the supply of power to the heater 210 when the voltage of the battery 16 is lower than predetermined minimum voltage.

In addition, in accordance with another aspect of the present disclosure, the aerosol-generating device may further include a voltage sensor 151 configured to detect voltage of the battery 16. When the voltage of the battery 16 is equal to or higher than predetermined voltage, the controller 17 may determine a time period corresponding to the first period to be a time period set for detection of the resistance of the heater 210. When the voltage of the battery 16 is lower than the predetermined voltage, the controller 17 may determine the time period corresponding to the first period in proportion to the voltage of the battery 16.

An operation method of an aerosol-generating device 10 in accordance with one aspect of the present disclosure may include turning on a switching element 160 electrically connected to a heater 210 in a first period in which power is supplied to the heater 210 heating an aerosol-generating substance from a battery 16, determining, in the first period, a duty ratio based on a signal from a resistance detection sensor 150 configured to output a signal corresponding to the resistance of the heater 210, and adjusting switching operation of the switching element 160 based on the determined duty ratio in a second period after the first period in which power is supplied to the heater 210 from the battery 16.

Certain embodiments or other embodiments of the disclosure described above are not mutually exclusive or distinct from each other. Any or all elements of the embodiments of the disclosure described above may be combined with another or combined with each other in configuration or function.

For example, a configuration “A” described in one embodiment of the disclosure and the drawings and a configuration “B” described in another embodiment of the disclosure and the drawings may be combined with each other. Namely, although the combination between the configurations is not directly described, the combination is possible except in the case where it is described that the combination is impossible Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An aerosol-generating device comprising:
a heater configured to heat an aerosol-generating substance;
a battery configured to supply power to the heater;
a resistance detection sensor configured to provide an output corresponding to resistance of the heater;
a switching element electrically coupled to the heater and being configured to permit the power to be supplied to the heater and to interrupt the power from being supplied to the heater; and
a controller configured to: control the switching element to permit the power to be supplied to the heater during a first period;
determine the resistance of the heater based on the output from the resistance detection sensor during the first period;
determine a duty ratio based on the determined resistance of the heater; and
control the switching element to alternatingly cause the power to be supplied to the heater, and to interrupt the power supplied to the heater, in a manner corresponding to the duty ratio during a second period.

2. The aerosol-generating device according to claim 1, wherein the first period and the second period are alternately repeated.

3. The aerosol-generating device according to claim 1, wherein a first time period corresponding to the first period is shorter than a second time period corresponding to the second period.

4. The aerosol-generating device according to claim 1, further comprising a voltage sensor configured to detect voltage of the battery,
wherein the controller is further configured to determine a time period corresponding to the first period based on the voltage of the battery detected by the voltage sensor.

5. The aerosol-generating device according to claim 4, wherein the time period corresponding to the first period is equal to or greater than a minimum time required for the controller to determine the duty ratio.

6. The aerosol-generating device according to claim 4, wherein a time period corresponding to the second period is a defined second time period.

7. The aerosol-generating device according to claim 4, wherein the controller is further configured to interrupt the power supplied to the heater based on the voltage of the battery being lower than a minimum voltage.

8. The aerosol-generating device according to claim 1, further comprising a voltage sensor configured to detect voltage of the battery,
wherein the controller is further configured to:
determine a time period corresponding to the first period to be a defined first time period based on the voltage of the battery being equal to or greater than a defined voltage; and
determine the time period corresponding to the first period in proportion to the voltage of the battery based on the voltage of the battery being less than the defined voltage.

9. The aerosol-generating device according to claim 1, further comprising a cartridge configured to contain the aerosol-generating substance in a liquid state,
wherein the heater is disposed in the cartridge in order to heat the aerosol-generating substance.

10. A method for operating an aerosol-generating device, the method comprising:
turning on a switching element electrically coupled to a heater in a first period in which power from a battery is supplied to the heater to heat an aerosol-generating substance;
determining, in the first period, a duty ratio based on an output from a resistance detection sensor associated with the heater; and
switching operation of the switching element to alternatingly cause the power to be supplied to the heater, and interrupt the power supplied to the heater, in a manner corresponding to the duty ratio during a second period.

11. An aerosol-generating device comprising:
a heater configured to heat an aerosol-generating substance;
a battery configured to supply power to the heater;
a sensor configured to provide a value corresponding to resistance of the heater;
a switch electrically coupled to the heater and having an on state and an off state, wherein the on state permits the power to be supplied to the heater and the off state interrupts the power from being supplied to the heater; and
a controller configured to:
control the switch to be in the on state to permit the power to be supplied to the heater during a first period;
determine the resistance of the heater based on the value of the sensor during the first period;
determine a duty ratio based on the determined resistance of the heater; and
alternatingly control the switch from the on state to the off state to corresponding cause the power to be supplied to the heater, and to interrupt the power supplied to the heater, according to the duty ratio during a second period.

12. The aerosol-generating device according to claim 11, wherein the sensor is a current sensor configured to sense current of the power supplied to the heater.

13. The aerosol-generating device according to claim 11, wherein the sensor is a voltage sensor configured to sense voltage of the power supplied to the heater.
